(19) United States
(12) Patent Application Publication
(10) Pub. No.: US 2010/0038731 A1
(43) Pub. Date: Feb. 18, 2010

(54) NON-VOLATILE MEMORY DEVICE

(75) Inventors: Robertus P. Van Kampen, Prauwstraat (NL); Robert Kazinczi, Helmond (NL)

Correspondence Address: PATTERSON & SHERIDAN, L.L.P., 3040 POST OAK BOULEVARD, SUITE 1500, HOUSTON, TX, 77056, US

(73) Assignee: Cavendish Kinetics, Ltd.

(21) Appl. No.: 12/441,254

(22) PCT Filed: Nov. 2, 2006
(86) PCT No.: PCT/GB06/04107

§ 371 Date: Mar. 13, 2009

(30) Foreign Application Priority Data
Nov. 3, 2005 (GB) 0522471.2

(51) Int. Cl. H01L 29/84; H01L 21/3205

(52) U.S. Cl. 257/415; 438/52; 257/E21.294; 257/E29.324

(57) ABSTRACT

A non-volatile memory device and method of manufacturing a non-volatile micro-electromechanical memory cell. The method comprises the first step of depositing a first layer of sacrificial material on a substrate by use of Atomic Layer Deposition The second step of the method is providing a cantilever (101) over at least a portion of the first layer of sacrificial material. The third step is depositing, by use of Atomic Layer Deposition, a second layer of sacrificial material over the first layer of sacrificial material and over a portion of the cantilever such that a portion of the cantilever is surrounded by sacrificial material. The fourth step is providing a further layer material (107) which covers at least a portion of the second layer of sacrificial material. Finally, the last step is etching away the sacrificial material surrounding the cantilever, thereby defining a cavity (102) in which the cantilever is suspended.

The present invention is directed to the field of Non-Volatile Memory (NVM) devices. There exists several known types of stand-alone NVM devices. One type of NVM which offers several advantages is a cantilevered micro-electromechanical system (MEMS) device.

The use of MEMS devices produce better memory performance and easier process integration and manufacturing, thereby reducing production costs. However, in order to implement MEMS-based NVMs in frontline processes for the manufacture of integrated devices, drastic downscaling of current cantilever-based switches is required. Because MEMS-based NVMs are essentially mechanical devices they are difficult to down-scale for use in integrated devices.

The lateral dimensions of a MEMS device can easily be scaled using known lithography processes. However, vertical scaling involves the provision of extremely thin mechanical and sacrificial layers. Providing such layers poses several problems relating to stress-induced curvature of the cantilever itself.

One problem is that an extremely thin cantilever layer will be more susceptible to surface related differential stresses. Another problem is that extremely thin sacrificial layers will produce extremely thin gaps above and below the cantilever layer and will thereby decrease the curvature tolerance of the device.

A further problem with creating integrated devices based on stand-alone Non-Volatile Memory architecture is finding suitable materials which can be used to scale down devices and are compatible with materials in the Back End Of Line (BEOL) processes used in typical CMOS fabrication facilities. Thus, because of their small size and manufacturing requirements, embedded Non-Volatile Memory devices are much more difficult to design and fabricate.

Accordingly, there exists a clear need for an integrated MEMS-based non-volatile memory unit which can be manufactured using BEOL processes.

In order to solve all of the above problems, the present invention provides a method of manufacturing a non-volatile micro-electromechanical memory cell, the method comprises the steps of:
depositing a first layer of sacrificial material on a substrate by use of Atomic Layer Deposition;
providing a cantilever over at least a portion of the first layer of sacrificial material;
depositing, by use of Atomic Layer Deposition, a second layer of sacrificial material over the first layer of sacrificial material and over a portion of the cantilever such that a portion of the cantilever is surrounded by sacrificial material;
providing a further layer of material which covers at least a portion of the second layer of sacrificial material; and
etching away the sacrificial material surrounding the cantilever, thereby defining a cavity in which the cantilever is suspended.

The further layer of material may be a layer of insulating material.

The further layer of material may be a layer of conductive material.

The cantilever may be provided by use of Atomic Layer Deposition.

The cantilever may be provided by use of Chemical Vapour Deposition.

Preferably, the portions of sacrificial material deposited in the step of depositing a first layer of sacrificial material and the step of depositing a second layer of sacrificial material are portions which surround the free end of the cantilever.

Preferably, the sacrificial material is a carbon-based material.

Preferably the further layer is provided by use of Atomic Layer Deposition.

Preferably, the step of providing a cantilever layer further comprises the step of:
coating at least one side of the cantilever layer with a conductive coating using Atomic Layer Deposition.

The present invention further provides a non-volatile micro-electromechanical memory cell which comprises:
a cantilever;
a cavity in which the cantilever is suspended, a portion of the cavity being formed by the removal of sacrificial material deposited using Atomic Layer Deposition.

The cantilever may have been formed using Atomic Layer Deposition.

Preferably, the portion of the cavity formed by the removal of sacrificial material deposited using Atomic Layer Deposition is a portion of the cavity which surrounds the free end of the cantilever.

Preferably, the cantilever is coated in a conductive material using Atomic Layer Deposition.

The present invention provides several advantages over the prior art. For example, because of its ultra-thin layers (i.e. 5-20 nanometres), electrode device construction is conducive to reduced programming currents during read operations of the device. Atomic Layer Deposition (ALD) allows controlling the deposition conditions layer by layer and hence ensuring a uniform stress distribution across the thickness of the device. This is critical to minimizing stress induced curvature effects. Another advantage is the extremely tight thickness control (for both mechanical and sacrificial layers) offered by the ALD technique, which results in more accurate switching voltage for the cantilever devices. Finally, ALD can be directly introduced in the MEMS/CMOS fabrication process flow.

Thus, the present invention provides extremely thin layers with excellent deposition control that allows exceptional film property control (e.g. composition, residual stress, thickness etc). These properties will directly improve performance, reliability and scaling of the memory devices.

Examples of the present invention will now be described with reference to the accompanying drawings in which:

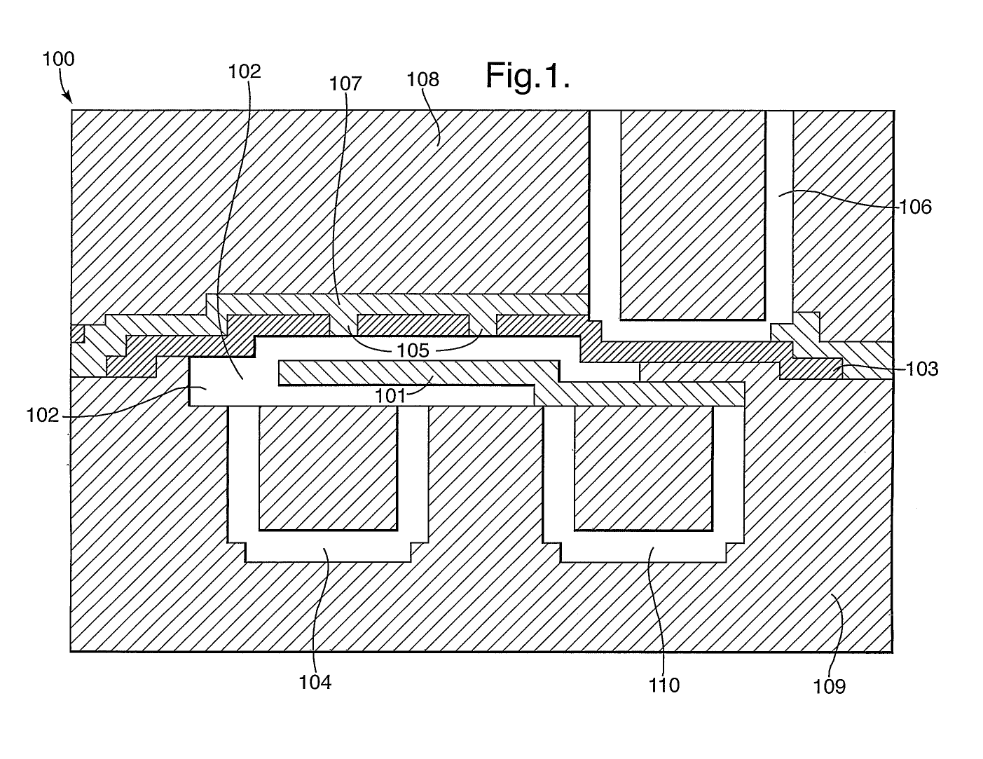

FIG. 1 is a representation of a first example of the present invention; and

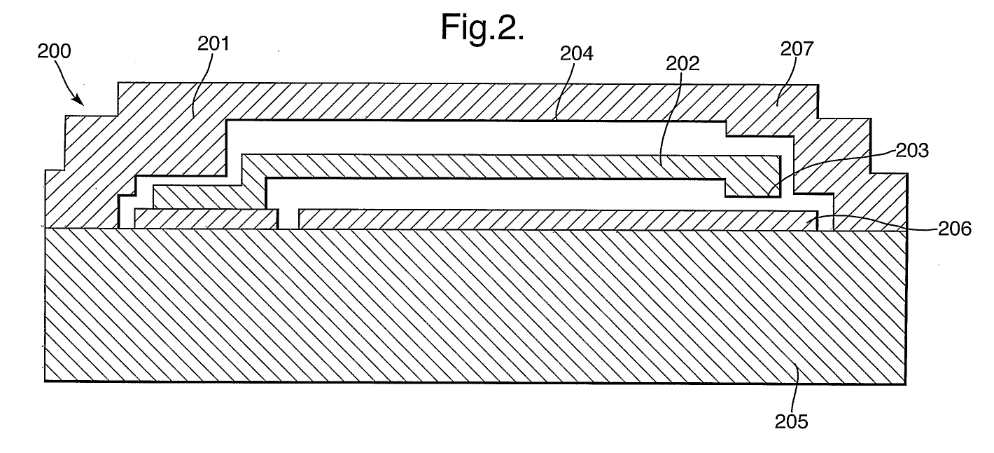

FIG. 2 is a representation of a second example of the present invention.

With reference to FIG. 1, a first example of the present invention will now be described. In the first example, the device 100 is a down-scaled version of a micro-electromechanical cantilever device partly fabricated by atomic layer deposition (ALD). A first layer of dielectric material 109 comprises a pull-down electrode 104 and a cantilever electrode 110.

Upon this layer of dielectric material 109, a cantilever 101 surrounded by sacrificial material (not shown) is formed through the alternate deposition of sacrificial material and cantilever material. A layer of conductive material 103 is then deposited over the second layer of sacrificial material. Two release holes 105 are then etched into the conducting layer 103. Then, the sacrificial material is etched through the release holes 105. When the sacrificial material is etched away, a cavity 102 is created in which the cantilever 101 is suspended.

An insulating layer 107 is then deposited over the conductive layer 103, the conductive layer 103 acting as a pull-up electrode. The pull-up electrode 103 is then electrically connected to a terminal 106 embedded into the top layer of dielectric material 108.

Thus, the integrated device comprises three terminals. Terminal 110 is connected to the cantilever 101, terminal 104 is used a pull-down electrode and terminal 106 is connected to the pull-up electrode 107.

The cantilever 101 itself is made of a very thin ALD layer of a material such as Ti, Al, TiN, TiAIN, TaN, TaSiN, W, WN, Ruthenium, Ruthenium oxide or Cobalt. The cantilever 101 can be made of one or more layers of the different materials described to form a composite cantilever. For example, Ruthenium may be deposited using ALD or other Chemical Vapour Deposition methods and has the advantage that it does not form volatile fluorides, chlorides, bromides or iodides owing to reactions between other materials present in the BEOL of semiconductor facilities. Ruthenium also forms a conductive oxide which leads to improved contact resistance in the semiconductor devices of the present invention.

The cavity 102 around the cantilever 101 is formed by removing or etching sacrificial layers. In the present invention, ALD is used to form the sacrificial layers. The ALD sacrificial materials include SiN, SiO₂, Al₂O₃, HfO₂, Ta₂O₅, TiO, Aluminate or silicates. The sacrificial material may be made of carbon-based materials such as, but not limited to, amorphous carbon.

If the sacrificial layer is formed from amorphous carbon, it can be formed by the decomposition of Hydrocarbon (or carbon containing gases) such as methane (CH₄) or acetylene C₂H₂. If acetylene is the decomposition gas, it decomposes in the plasma to form a layer of amorphous carbon on the surface of the substrate. In this example, the typical required thicknesses range is from 25 nm to 500 nm. Etch materials should be inert with respect to the metal layer so that there is no degradation of material properties. Alternatively, a carbon fluoride gas such as CF₄ can be used when the film containing fluorine is to be formed.

Typically, the amorphous carbon layer also has a thickness in the range of about 25 nm to about 500 nm. The amorphous carbon layer may also be used as a hardmask which may perform as a stop for chemical/mechanical polishing techniques to allow selective removal of materials while protecting underlying materials, such as the dielectric material layers, from damage during etching or from polishing methods.

The amorphous carbon material of the sacrificial layer can be removed by etching with oxygen (a normal plasma applied at room temperature or heated) or a hydrogen containing plasma such as a high density hydrogen (here the substrate is heated to 300 C. at 10 torr) plasma. Etch rates are such that the undercut is typically 30 nm/min.

Now, again with reference to FIG. 1, the operation of a device in accordance with one example of the present invention will now be described. When a voltage is applied between the pull-down electrode 104 and the cantilever 101, the cantilever 101 is urged towards the pull-down electrode 104 until the cantilever 101 and the pull-down electrode 104 come into contact, which permits charge transfer. This defines the ON state of the device. When a voltage is applied between the cantilever 101 and the pull-up electrode 103, the cantilever 101 is urged out of contact with the pull-down electrode 104. This defines the OFF state of the device.

Now, with reference to FIG. 2, a second example of the present invention will now be described. In this second example, another three-terminal memory device will now be described. A bottom electrode 206 is first deposited onto a substrate 205. Then, the bottom electrode 206 is patterned and etched.

In this second example, a protrusion 203 is formed at the free end of the cantilever 202. All but one layer is deposited with physical vapour deposition (PVD) and chemical vapour deposition (CVD). The layer forming the gap under the protrusion 203 is deposited by ALD. The gap under the cantilever 202 is formed in a two-step sacrificial layer deposition.

The first step comprises depositing a “conventional” sacrificial layer (e.g. PECVD SIN) and etching away a “via” down to the bottom electrode 206 under the area defining the protrusion 203.

The second comprises the step of depositing an ultra-thin ALD sacrificial layer which defines the gap under the cantilever protrusion 203 that will contact the bottom electrode 206. An ultra-thin ALD sacrificial layer is also be deposited above the free end of the cantilever 202. This will permit a very small gap to be created between the free end of the cantilever 202 and the conducting cap 201 which will be deposited after. Although the sacrificial layer directly above the free end of the cantilever 202 is be deposited by ALD, the sacrificial layer above the rest of the cantilever 202 may be also be deposited using any known means.

Then, an insulating layer 204 is formed over the sacrificial layer. The insulating layer need only cover the area directly above the free end of the cantilever 202. The insulating layer may also be deposited using ALD.

Finally, a conducting cap 201 is deposited over the upper sacrificial layer and the insulating layer 204 and the sacrificial layers are then etched away, leaving the cantilever 202 surrounded by a cavity. Also, there will be a very thin gap above and below the free end of the cantilever 202.

In this example, the thin gap at the protrusions restricts the motion of the cantilever 202. This provides a number of advantages, for example, decreased impact of non-linear forces like van der Waals and Casimir forces.

In yet a further example of the present invention, the cantilever device shown in FIG. 2 consists of a thicker mechanical layer (eg. PVD or CVD the usual materials) and an ALD conductive coating, such as ruthenium oxide, on the top and/or bottom surface of the cantilever which ensures good contact properties. In the simplest configuration the ALD layers are not patterned separately but in one step together with the mechanical layer to form the multi-layer cantilever. The sacrificial layers can be ALD or non-ALD layers (depending on the required thickness).

The ALD contact coating is applicable not only to the cantilever switch but to other micromechanical structures for switches so as to improve contact in RF or IN switches. Accordingly, a person skilled in the art will appreciate that the present invention may equally be applied for other movable and non-movable micromechanical structures formed in a cavity such as a fuse, switches or other charge transfer elements.

1. A method of manufacturing a non-volatile micro-electromechanical memory cell, the method comprising the steps of:
depositing a first layer of sacrificial material on a substrate by use of Atomic Layer Deposition;
providing a cantilever over at least a portion of the first layer of sacrificial material;
depositing, by use of Atomic Layer Deposition, a second layer of sacrificial material over the first layer of sacrificial material and over a portion of the cantilever such that a portion of the cantilever is surrounded by sacrificial material;
providing a further layer of material which covers at least a portion of the second layer of sacrificial material; and
etching away the sacrificial material surrounding the cantilever, thereby defining a cavity in which the cantilever is suspended.

2. The method of claim 1 wherein the further layer of material is a layer of insulating material.

3. The method of claim 1 wherein the further layer of material is a layer of conductive material.

4. The method of claim 1, wherein the cantilever is provided by use of Atomic Layer Deposition.

5. The method of claim 1, wherein the cantilever is provided by use of Chemical Vapour Deposition.

6. The method of claim 1, wherein the portions of sacrificial material deposited in the step of depositing a first layer of sacrificial material and the step of depositing a second layer of sacrificial material are portions which surround the free end of the cantilever.

7. The method of claim 1, wherein the sacrificial material is a carbon-based material.

8. The method of claim 1, wherein the further layer is provided by use of Atomic Layer Deposition.

9. The method of claim 5, wherein the step of providing a cantilever layer further comprises the step of:
coating at least one side of the cantilever layer with a conductive coating using Atomic Layer Deposition.

10. A non-volatile micro-electromechanical memory cell comprising:
a cantilever;
a cavity in which the cantilever is suspended, a portion of the cavity being formed by the removal of sacrificial material deposited using Atomic Layer Deposition.

11. The memory cell of claim 10, wherein the cantilever was formed using Atomic Layer Deposition.

12. The memory cell of claim 10, wherein the portion of the cavity formed by the removal of sacrificial material deposited using Atomic Layer Deposition is a portion of the cavity which surrounds the free end of the cantilever.

13. The memory cell of claim 10, wherein the cantilever is coated in a conductive material using Atomic Layer Deposition.

14. The method of claim 2, wherein the cantilever is provided by use of Atomic Layer Deposition.

15. The method of claim 3, wherein the cantilever is provided by use of Atomic Layer Deposition.

16. The method of claim 2, wherein the cantilever is provided by use of Chemical Vapour Deposition.

17. The method of claim 3, wherein the cantilever is provided by use of Chemical Vapour Deposition.

18. The method of claim 6, wherein the step of providing a cantilever layer further comprises the step of:
coating at least one side of the cantilever layer with a conductive coating using Atomic Layer Deposition.

19. The method of claim 7, wherein the step of providing a cantilever layer further comprises the step of:
coating at least one side of the cantilever layer with a conductive coating using Atomic Layer Deposition.

20. The method of claim 8, wherein the step of providing a cantilever layer further comprises the step of:
coating at least one side of the cantilever layer with a conductive coating using Atomic Layer Deposition.
